(19) United States
(12) Patent Application Publication
(10) Pub. No.: US 2012/0243155 A1
(43) Pub. Date: Sep. 27, 2012

(54) CONDUCTIVE METAL NUB FOR ENHANCED ELECTRICAL INTERCONNECTION, AND INFORMATION HANDLING SYSTEM UTILIZING SAME

(75) Inventors: Luis J. Matienzo, Endicott, NY (US); Norman A. Card, Lockwood, NY (US); Daniel C. VanHart, Conklin, NY (US); John J. Konrad, Endicott, NY (US); Frank D. Egitto, Binghamton, NY (US); Rabindra N. Das, Vestal, NY (US)

(73) Assignee: ENDICOTT INTERCONNECT TECHNOLOGIES, INC., Endicott, NY (US)

(21) Appl. No.: 13/009,922

(22) Filed: Jan. 20, 2011

(51) Int. Cl. H05K 7/14; H01L 21/50

(52) U.S. Cl. 361/679.02; 438/107; 174/257; 361/757; 257/E21.499

(57) ABSTRACT

A method of forming a circuitized substrate utilizing a conductive nub structure for enhanced interconnection integrity by using a joining core layer with copper outer layer on it, and forming thru-holes in the joining layer. Placing conductive adhesive in the thru-hole prior to removing the copper outer layers from the joining core layer creates an adhesive bump on joining core layer that engages a conductive secondary metal nub placed on the circuitized substrate-to-joining layer contact points, thus creating an enhanced connection between the layers.

### FIELD OF THE INVENTION

The present invention relates to the preparation of electrical interconnects between circuit boards and, more specifically, to an electrical interconnection process that enhances the Z-axis electrical connection between layers, and to a structure wherein a copper pad is utilized as a contact point in a circuitized substrate.

### BACKGROUND OF THE INVENTION

The needs of the semiconductor marketplace continue to drive density into semiconductor packages. Traditionally, greater wiring densities have been achieved by reducing the dimensions of vias, lines, and spaces, increasing the number of wiring layers, and utilizing blind and buried vias. However, each of these approaches, for example, those related to drilling and plating of high aspect ratio vias, reduced conductance of narrow circuit lines, and increased cost of fabrication related to additional wiring layers, includes inherent limitations.

PCBs, chip carriers and related products used in many of today's technologies must include multiple circuits in a minimum volume or space. Typically, such products comprise a stack of layers of signal, ground and/or power planes separated from each other by at least one layer of electrically insulating dielectric material. The circuit lines or pads (e.g., those of the signal planes) are often in electrical contact with each other by plated holes passing through the dielectric layers. The plated holes are often referred to as vias if internally located, blind vias if extending a predetermined depth within the board from an external surface, or plated-thru-holes (PTHs) if extending substantially through the board's full thickness. The term thru-hole as used herein is meant to include all three types of such board openings.

Complexity of these products has increased significantly in recent years. PCBs for mainframe computers may have as many as seventy-two layers of circuitry or more, with the complete stack having a thickness of as much as about 0.800 inch (800 mils). These boards are typically designed with three or five mil wide signal lines and twelve mil diameter thru-holes. Increased circuit densification requirements seek to reduce signal lines to a width of two mils or less and thru-hole diameters to two mils or less. Many known commercial procedures, especially those of the nature described herein, are incapable of economically forming these dimensions now desired by the industry. Such processes typically comprise fabrication of separate innerlayer circuits (circuitized layers), which are formed by coating a photosensitive layer or film over the copper layer of a copper clad innerlayer base material. The photosensitive coating is imaged and developed and the exposed copper is etched to form conductor lines. After etching, the photosensitive film is stripped from the copper, leaving the circuit pattern on the surface of the innerlayer base material. This processing is also referred to as photolithographic processing in the PCB art and further description is not deemed necessary.

After the formation of the individual innerlayer circuits, a multilayer stack is formed by preparing a lay-up of core innerlayers, ground planes, power planes, etc., typically separated from each other by a dielectric prepreg comprising a layer of glass cloth (typically fiberglass) impregnated with a partially cured material, typically a B-stage epoxy resin. The top and bottom outer layers of the stack usually comprise copper clad, glass-filled epoxy planar substrates with exterior surfaces of the stack comprising copper cladding. The stack is laminated to form a monolithic structure using heat and pressure to fully cure the B-stage resin. The stack so formed typically has metal (usually copper) cladding on both of its exterior surfaces. Exterior circuit layers are formed in the copper cladding using procedures similar to the procedures used to form the innerlayer circuits. A photosensitive film is applied to the copper cladding. The coating is exposed to patterned activating radiation and developed. An etchant is then used to remove copper bared by the development of the photosensitive film. Finally, the remaining photosensitive film is removed to provide the exterior circuit layers.

The aforementioned thru-holes (also often referred to as interconnects) are used in many such substrates to electrically connect individual circuit layers within the structure to each other and to the outer surfaces. The thru-holes typically pass through all or a portion of the stack. Thru-holes are generally formed prior to the formation of circuits on the exterior surfaces by drilling holes through the stack at appropriate locations. Following several pre-treatment steps, the walls of the holes are catalyzed by contact with a plating catalyst and metallized, typically by contact with an electroless or electrolytic copper plating solution to form conductive pathways between circuit layers. Following formation of the conductive thru-holes, exterior circuits, or outerlayers, are formed using the procedure described above.

In semiconductor chip fabrication and packaging, the steps of etching different layers are among the more critical and crucial steps. Methods that are commonly used for the selective etching of organic polymers, including photoresists and dielectric substrates, include dry etching processes such as oxygen plasma etching and reactive ion etching in an oxygen containing plasma.

### DISCUSSION OF RELATED ART

U.S. Pat. No. 7,342,183, by Egitto, et al., granted Mar. 11, 2008 for CIRCUITIZED SUBSTRATE WITH SINTERED PASTE CONNECTIONS, MULTILAYERED SUBSTRATE ASSEMBLY, ELECTRICAL ASSEMBLY AND INFORMATION HANDLING SYSTEM UTILIZING SAME discloses a circuitized substrate which includes a high temperature dielectric material in combination with a low temperature conductive paste, the paste including an organic binder component and at least one metallic component. The flakes of the metallic component are sintered to form a conductive path through the dielectric when the dielectric is used as a layer in the substrate.

U.S. Pat. No. 7,334,323 by Egitto, et al., granted Feb. 26, 2008 for METHOD OF MAKING MULTILAYERED CIRCUITIZED SUBSTRATE ASSEMBLY HAVING SINTERED PASTE CONNECTIONS discloses a method of making a circuitized substrate which includes a high temperature dielectric material in combination with a low temperature conductive paste, the paste including an organic binder component and at least one metallic component. The flakes of the metallic component are sintered to form a conductive path through the dielectric when the dielectric is used as a layer in the substrate.

U.S. Pat. No. 7,301,108 by Egitto, et al., granted Nov. 27, 2007 for MULTI-LAYERED INTERCONNECT STRUCTURE USING LIQUID CRYSTALLINE POLYMER DIELECTRIC discloses a multi-layered interconnect structure and method of formation. In a first embodiment, two liquid crystal polymer (LCP) dielectric layers are directly bonded to opposing surfaces of a thermally conductive layer, with no extrinsic adhesive material bonding the thermally conductive layer with either LCP dielectric layer. In a second embodiment, two substructures are directly bonded to opposing surfaces of a LCP dielectric joining layer, with no extrinsic adhesive material bonding the LCP dielectric joining layer with either of the two substructures.

U.S. Pat. No. 7,015,590 by Jong et al., granted Mar. 21, 2006 for REINFORCED SOLDER BUMP STRUCTURE AND METHOD FOR FORMING A REINFORCED SOLDER BUMP discloses a reinforced solder bump connector structure that is formed between a contact pad arranged on a semiconductor chip and a ball pad arranged on a mounting substrate. The semiconductor chip includes at least one reinforcing protrusion extending upwardly from a surface of an intermediate layer. The mounting substrate includes at least one reinforcing protrusion extending upwardly from a ball pad, the protrusions from both the chip and the substrate being embedded within the solder bump connector. In some configurations, the reinforcing protrusion from the contact pad and the ball pad are sized and arranged to have overlapping under portions. These overlapping portions may assume a wide variety of configurations that allow the protrusions to overlap without contacting each other including pin arrays and combinations of surrounding and surrounded elements. In each configuration, the reinforcing protrusions will tend to suppress crack formation and/or crack propagation thereby improving reliability.

U.S. Pat. Nos. 6,790,305 and 6,955,849, by Curcio et al., granted Sep. 14, 2004 and Oct. 18, 2005, respectively, for METHOD AND STRUCTURE FOR SMALL PITCH Z-AXIS ELECTRICAL INTERCONNECTION disclose a method for producing small pitch z-axis electrical interconnections in layers of dielectric materials that are applied to printed wiring boards and diverse electronic packages. A method of parallel fabrication of intermediate structures that are subsequently joined to form a final structure is also disclosed. In addition there is provided a z-interconnected electrical structure, employing dielectric materials such as resin coated copper, employable in the manufacture of diverse type of electronic packages, including printed wiring boards (PWBs), substrates, multi-chip modules and the like.

U.S. Pat. No. 6,826,830 by Egitto, et al., granted Dec. 7, 2004 for METHOD AND STRUCTURE FOR SMALL PITCH Z-AXIS ELECTRICAL INTERCONNECTIONS discloses a multi-layered interconnect structure and method of formation. In a first embodiment, two liquid crystal polymer (LCP) dielectric layers are directly bonded to opposing surfaces of a thermally conductive layer, with no extrinsic adhesive material bonding the thermally conductive layer with either LCP dielectric layer. In a second embodiment, two substructures are directly bonded to opposing surfaces of a LCP dielectric joining layer, with no extrinsic adhesive material bonding the LCP dielectric joining layer with either of the two substructures.

U.S. Pat. No. 7,279,412 by Mok, et al., granted Oct. 9, 2007 for PARALLEL MULTI-LAYER PRINTED CIRCUIT BOARD HAVING IMPROVED INTERCONNECTION AND METHOD FOR MANUFACTURING THE SAME describes a multi-layer printed circuit board and a method for the manufacture thereof. Circuit layers and insulating layers are alternately stacked so that via holes of the circuit layers provided with plated inner walls without application of additional plating and conductive paste-filling steps are connected to via holes of the insulating layers filled with a conductive paste.

The previously disclosed United States patents fail to adequately describe the present invention's interconnect structure preparation techniques to enhance the physical contact connection of Z-interconnect structures.

It is therefore an object of the invention to provide an interconnect structure preparation technique to enhance the electrical and physical contact of Z-interconnect structures.

It is also an object of this invention to use a metal pad structure and conductive adhesive to enhance circuit board interfacial adhesion between adjacent circuit boards after lamination.

It is also an object of this invention to utilize the addition of the metal pad structure to increase dimensional stability and electrical connection during lamination.

### SUMMARY OF THE INVENTION

According to the present invention, there is provided a structure and method of utilizing an additional metal pad on top of metallized surfaces feature, such as pads and lines, or wherever interconnections are desired.

### BRIEF DESCRIPTION OF THE DRAWINGS

The objects and advantages of the present invention will become more readily apparent to those skilled in the art after reviewing the following detailed description and the accompanying drawings, wherein:

FIG. 1 is an exploded side view of a prior art interconnect structure;

FIG. 2 is a side view of the prior art laminated interconnect structure of FIG. 1;

FIG. 3 is a photomicrograph cross sectional view of a sample of the interconnect structure of FIG. 1;

FIG. 4 is an enlarged close-up sectional view of the interconnect structure of FIG. 3;

FIG. 5 is a side view a joining core of the present invention;

FIG. 6 is a side view the joining core of FIG. 5, subsequent to chemical mechanical polishing (CMP);

FIG. 7 is a side view a circuitized substrate with Cu pad containing studs;

FIG. 8 is a side view a lay-up of circuitized substrate and joining cores prior to lamination;

FIG. 9 is a side view of the laminated interconnect structure of FIG. 8;

FIG. 10 is a photomicrograph cross sectional view of a sample of the interconnect structure of FIG. 9;

FIG. 11 is an enlarged close-up sectional view of the interconnect structure of FIG. 10; and

FIG. 12 represents an information handling system according to one aspect of the invention, which is capable of utilizing one or more of the electronic packages taught herein.

For the sake of clarity and brevity, like elements and components of each embodiment will bear the same designations throughout the description.

### DESCRIPTION OF THE PREFERRED EMBODIMENT

Generally speaking, the present invention is a method and structure for a more efficient interconnection of metallized surfaces and adhesive. The interconnection is achieved by incorporating a second metal structure disposed on the metallized surfaces, such as pads, lines or whatever interconnection between layers is desired. The use of a metallized pad on top of connecting points enhances the physical contact between the pad and a column of conductive adhesive that results in improved electrical performance of layers.

For a better understanding of the present invention, together with other and further objects, advantages and capabilities thereof, reference is made to the following disclosure and appended claims.

By the term “circuitized substrate” as used herein is meant to define a structure including at least one dielectric layer having at least one surface having thereon at least one circuit. Examples of dielectric materials suitable for use in such structures include fiberglass-reinforced or non-reinforced epoxy resins (sometimes referred to simply as FR4 material, meaning its Flame Retardant rating), polytetrafluoroethylene (Teflon), polyimides, polyamides, cyanate resins, photoimageable materials, liquid crystal polymers (LCP), and other like materials, or combinations thereof. Examples of electrically conductive materials for the circuit layers include copper or copper alloy. If the dielectric is a photoimageable material, it is photoimaged or photopatterned, and developed to reveal the desired circuit pattern, including the desired opening(s) as defined herein, if required. The dielectric material may be curtain coated or screen applied, or it may be supplied as a dry film or in other sheet form.

By the term “electroplating” as used herein is meant a process by which a metal in its ionic form is supplied with electrons to form a non-ionic coating on a desired substrate. The most common system involves: a chemical solution which contains the ionic form of the metal, an anode (positively charged) which may consist of the metal being plated (a soluble anode) or an insoluble anode (usually carbon, platinum, titanium, lead, or steel), and finally, a cathode (negatively charged) where electrons are supplied to produce a film of non-ionic metal.

By the term “electroless plating” (also known as chemical or auto-catalytic plating) as used herein is meant a non-galvanic type of plating method that involves several simultaneous reactions in an aqueous solution, which occur without the use of external electrical power. The reaction is accomplished when hydrogen is released by a reducing agent, normally sodium hypophosphite, and oxidized thus producing a negative charge on the surface of the part.

By the term “electronic package” as used herein is meant a circuitized substrate assembly as taught herein having one or more ICs (e.g., semiconductor chips) positioned thereon and electrically coupled thereto. In a multi-chip electronic package, for example, a processor, a memory device and a logic chip may be utilized and oriented in a manner designed for minimizing the limitation of system operational speed caused by long connection paths. Some examples of such packages, including those with a single chip or a plurality thereof, are also referred to in the art as chip carriers.

By the term “etch” and “etching” as used herein is meant a process by where a surface of a substrate is either selectively etched using a photoresist or covered by a mask prior to plasma treating, both methods are meant to transfer an image onto the substrate for subsequent further processing.

By the term “information handling system” as used herein is meant any instrumentality or aggregate of instrumentalities primarily designed to compute, classify, process, transmit, receive, retrieve, originate, switch, store, display, manifest, measure, detect, record, reproduce, handle or utilize any form of information, intelligence or data for business, scientific, control or other purposes. Examples include personal computers and larger processors such as computer servers and mainframes. Such products are well known in the art and are also known to include PCBs and other forms of circuitized substrates as part thereof, some including several such components depending on the operational requirements thereof.

By the term “laser ablation” as used herein is meant the process of removing material from a solid surface by irradiating it with a laser beam. At low laser flux, the material is heated by the absorbed laser energy and evaporates or sublimes. At high laser flux, the material is typically converted to a plasma. The term laser ablation as used herein refers to removing material with a pulsed laser as well as ablating material with a continuous wave laser beam if the laser intensity is high enough.

By the term “thru-hole” as used herein to define an electrically conductive structure formed within a circuitized substrate as defined herein and is meant to include three different types of electrically conductive elements. It is known in multilayered PCB's and chip carriers to provide various conductive interconnections between various conductive layers of the PCB and carrier. For some applications, it is desired that electrical connection be made with almost if not all of the conductive layers. In such a case, thru-holes are typically provided through the entire thickness of the board, in which case these are often also referred to as “plated thru holes” or PTHS. For other applications, it is often desired to also provide electrical connection between the circuitry on one face of the substrate to a depth of only one or more of the inner circuit layers. These are referred to as “blind vias”, which pass only part way through (into) the substrate. In still another case, such multilayered substrates often require internal connections (“vias”) which are located entirely within the substrate and covered by external layering, including both dielectric and conductive. Such internal “vias”, also referred to as “buried vias”, may be formed within a first circuitized substrate which is then bonded to other substrates and/or dielectric and/or conductive layers to form the final, multilayered embodiment. Therefore, for purposes of this application, the term “thru hole” is meant to include all three types of such electrically conductive openings.

A potential problem with conventional Z-interconnect structures occurs when the conductive adhesive in the joining core vias does not protrude above the surface of the joining core or is recessed below the surface of the joining core. This condition can occur due to excessive removal of adhesive paste during conventional chemical mechanical polishing (CMP) processing if paste is scooped from the joining core vias, thus negatively affecting yields.

These conditions may subsequently lead to inadequate contact between the conductive paste and the circuitized substrates to which the joining core is mated. Lack of contact results in yield loss during composite lamination. Metal nubs make reliable electrical connections even with conductive adhesive affected by the CMP process. Overall, a simpler structure that is more electrically forgiving can be obtained by the inventive method described herein. The application of this connection concept using the metal nubs can be extended to other electronic structures, such as circuit boards that require good contact by inter-penetration between connections on adjacent layers.

This invention encompasses a new design for Z-interconnection of planes utilizing conductive adhesives. More efficient interconnection of metallized surface or surfaces and adhesive is achieved by the incorporation of a second metal structure on top of the metallized surfaces of pads, lines, or whatever category of interconnection is desired. Prototypes produced by lamination experiments with structures containing the present invention have demonstrated that the use of a metallized pad on top of a connecting point enhances the physical contact between the pad and a column of conductive adhesive, resulting in improved electrical performance.

A comparison of a resulting cross-sectional view of a conventional Z-interconnect structure between an Ag-based conductive adhesive column and a metallized pad and a cross-sectional view of a sample of the current invention reveals that the inventive structure results in better interpenetration, electrical contact, and joint strength.

Other definitions are readily ascertainable from the detailed descriptions provided herein.

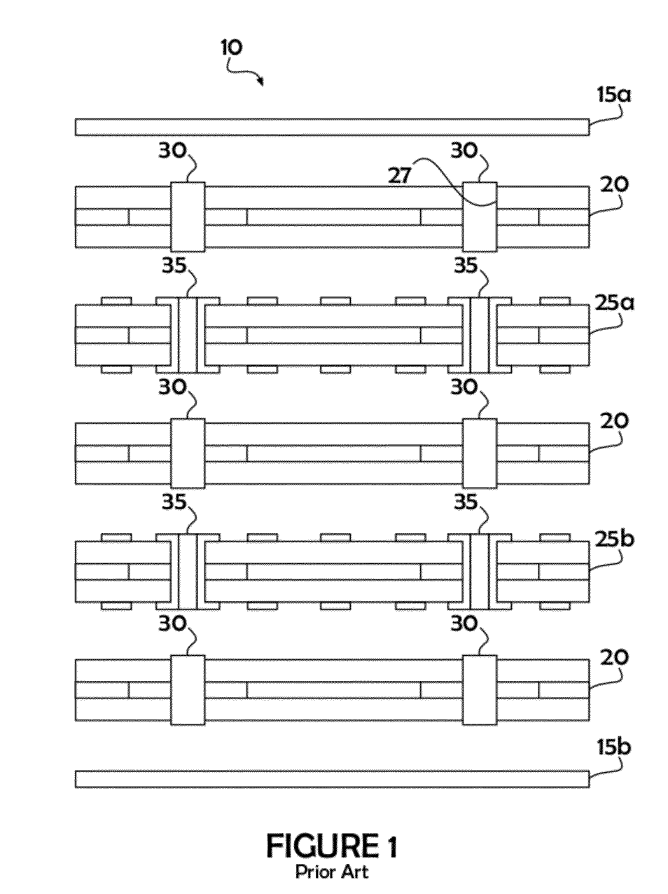

Referring now to the drawings, FIG. 1 shows an exploded side view of a prior art interconnect structure 10 showing copper cladding 15a and 15b, three joining members 20, and two, two-signal/one power-plane (2S/1P) circuitized substrates 25a and 25b. Joining members 20 contain conductive adhesive 30 in drilled thru holes 27, that, when subjected to the heat and pressure of lamination, allow the conductive adhesive 30 to flow to connect the plated through holes (PTHs) 35 of the 2S/1P circuitized substrates 25a of one layer with another layer of 2S/1P circuitized substrate 25b. The creation of PTHs, the application of conductive adhesive, and lamination are known and further description is not required.

FIG. 2 is the interconnect structure 10 of FIG. 1 after lamination has been performed showing a PTH 35 of circuitized substrate 25a utilizing conductive adhesive 30 of joining core 20 connected to a second layer of circuitized substrate 25b, and subsequently electrically connecting copper cladding 15a to copper cladding 15b.

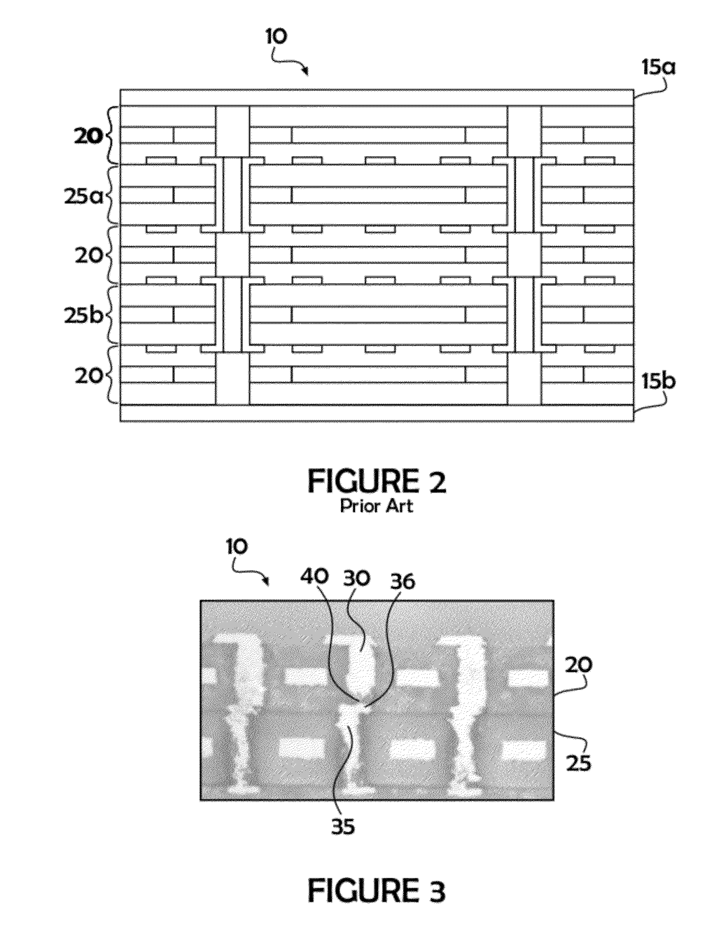

While FIG. 1 and FIG. 2 are drawn to show structure detail as it would be in an perfect world, the actual world does not necessarily support the drawings as fact. FIG. 3 is a photomicrograph of a cross-sectioned interconnect structure 10 of a standard Z-interconnect showing void a region 40 at the conductive adhesive 30/pad 36 of PTH 35 interface. This can occur due to excessive removal of adhesive paste during conventional CMP processing if paste 30 is scooped from the joining core vias 27, resulting in an empty space between electrical interconnects of joined layers. In this instance, the signals carried by the junction can be reduced or attenuated, or all together eliminated, resulting in a failure of the assembly.

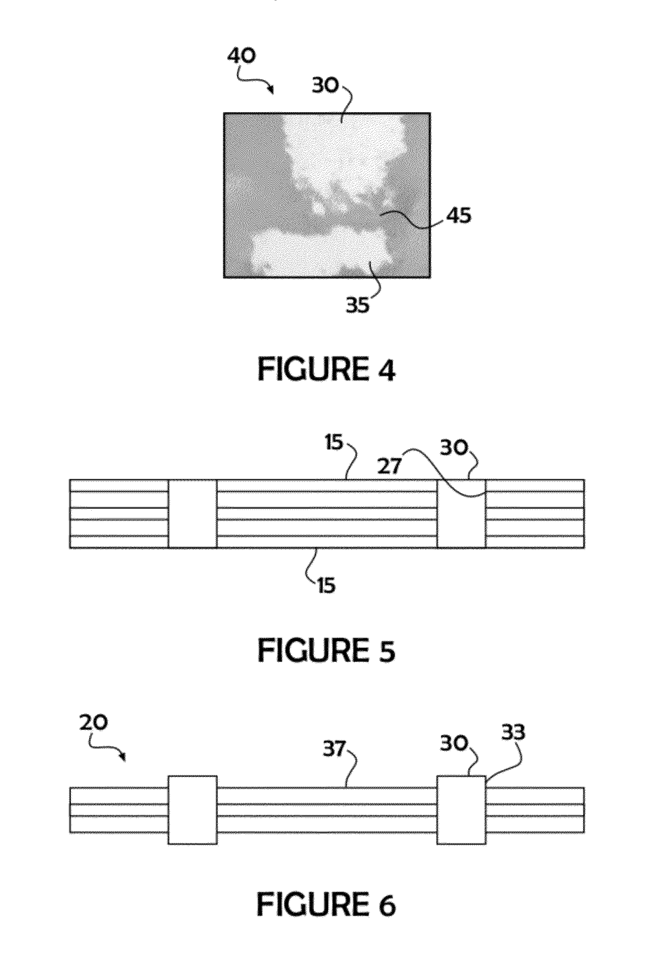

FIG. 4 is an enlarged view of the void region 40 depicting the actual void 45 showing the apparent discontinuous link of the connection of conductive adhesive 30 and PTH 35 interface. As will be shown hereinbelow, this connection method can be enhanced.

FIGS. 5-9 illustrate the steps used to assemble the current invention. Standard techniques are used to create individual joining members 20 and circuitized substrates 55. In this group of figures, circuitized substrates 55 are depicted by the edge surface 52 that will interface with joining core 20, unlike the complete layer stack up shown in FIG. 2.

Continuing with FIG. 5, there is shown the known process for creating a conductive adhesive bump 33 (FIG. 6) by filling drilled thru holes 27 with conductive adhesive 30 and, in this embodiment, removing cladding 15 via chemical etching or another known process. Cladding 15 may be copper, stencil, or other suitable material designed to create a thin layer of conductive adhesive 30 after removal.

FIG. 6 shows a conductive adhesive bump 33 that is elevated above surface 37 after removal of cladding 15 to complete joining core 20, similar to joining core 20 of FIG. 1.

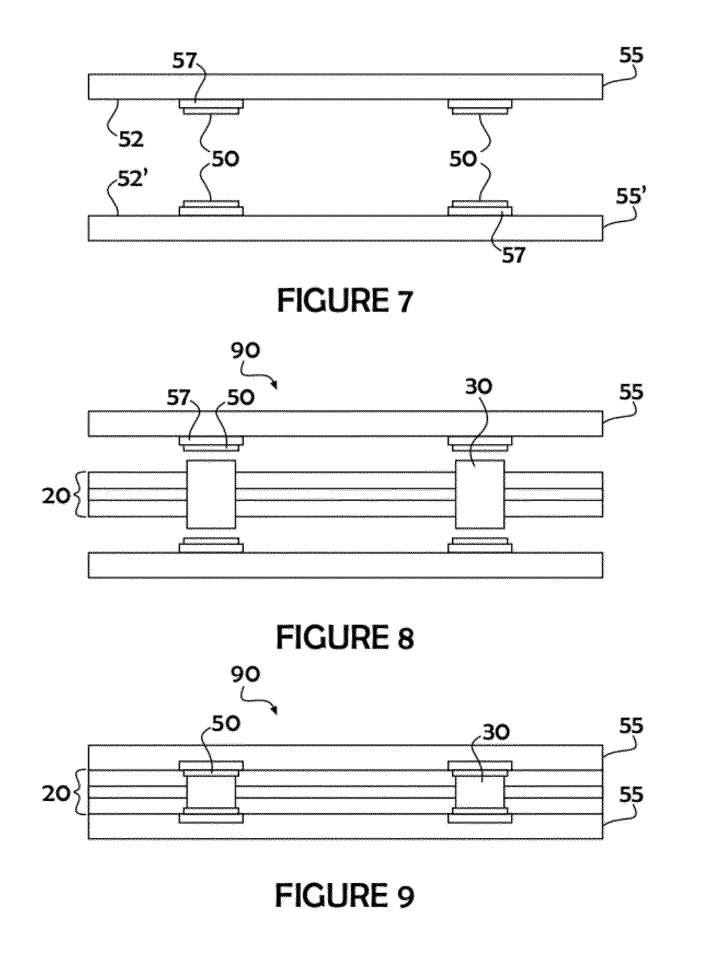

FIG. 7 shows a top and bottom surface 52 and 52′ of two individual circuitized substrates 55 and 55′ that are positioned surrounding joining core 20. Metal nub 50 is built, depending on frame of reference, on top of a metallized surface 57 to create a small metal structure that increases the height from surface 52 and 52′ to permit a more substantial interfacial contact with an adjacent layer containing conductive adhesive 30. Metallized surface 57 can consist of features such as pads, lines or wherever interconnections between layers is desired.

Metal nub 50 is a small column of conductive material that is formed using the same processes that create the circuitized substrate 55 on which it is located. Better interpenetration, electrical contact, and joint strength is achieved with the new design.

FIG. 8 shows an expanded side view of circuitized substrates 90 showing two facing surfaces 52 and 52′ of circuitized substrates 55 and 55′ and joining core 20. Joining core 20 contains conductive adhesive 30 in drilled thru-holes 27, with two facing surfaces 52 and 52′ of circuitized substrates 55 and 55′ containing metallized surfaces 57, with metal nub 50 located thereon. FIG. 9 is the circuitized substrate 90 of FIG. 8 after lamination has been performed.

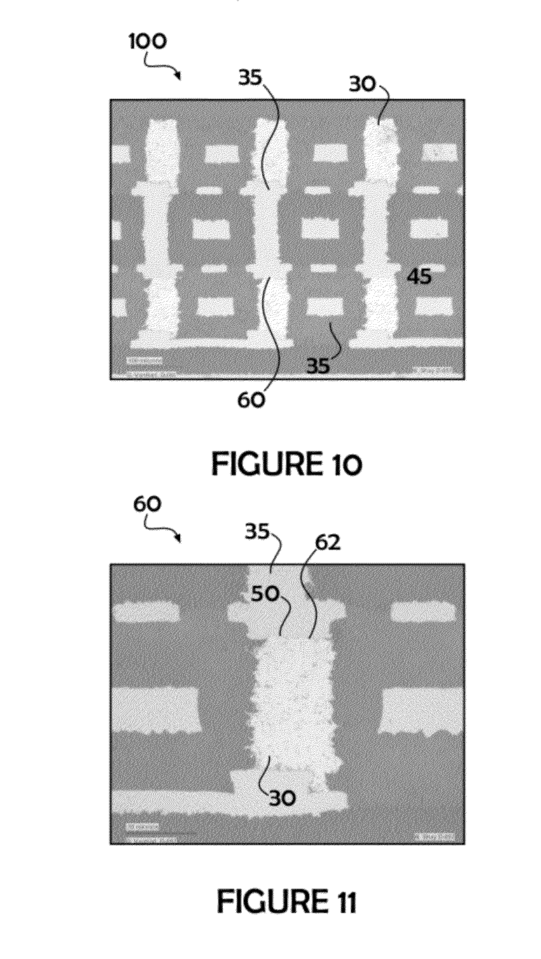

Again, FIG. 8 and FIG. 9 are drawn to show detail as it would be in an ideal world. FIG. 10 is a photomicrograph of an actual cross-sectioned PCB 100 of a current invention showing a connection that has no voids, similar to FIG. 3 in the interface region 60 of metal nub 50 and conductive adhesive 30.

FIG. 11 is an enlarged view of the interface region 60 (FIG. 10) depicting the lack of a void, showing the continuous bond of conductive adhesive 30 and metal nub 50 at the interface 62 of the connection.

In accordance with the present invention, the lamination of product using Asahi dielectric material (joining core material) results in a material flow of joining core 20 material around the plated pads 57 and metal nubs 50 on the circuitized substrate 55 and 55′. Circuitized substrate 55 fluoropolymer layers do not flow under these conditions. The optimized lamination conditions utilize a temperature of 200° C. at 1600 psi for 2 hours.

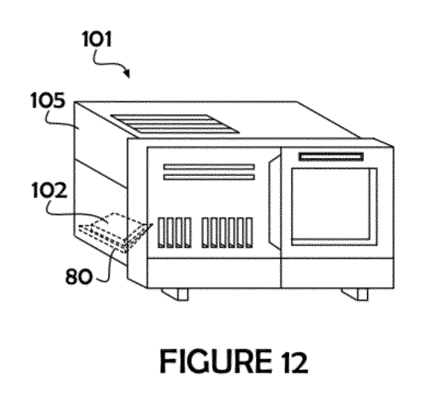

As stated, each circuitized substrate formed in accordance with the teachings herein may be utilized within a larger substrate of known type such as a PCB, chip carrier or the like. FIG. 10 illustrates one of these larger components, PCB 100. PCB 100 may be positioned within and electrically coupled to an information handling system 101 as shown in FIG. 12, which may be in the form of a personal computer, mainframe, computer server, etc. PCB 100, as shown, is typically electrically coupled to other PCBs 100 to form a processing assemblage within information handling system 101. As mentioned above, the invention is not limited to the numbers shown. For example, one or more circuitized substrates 90, each forming a particular circuitized “core” (e.g., a “power core”) within the PCB 100, may be utilized to afford the PCB the highly advantageous teachings of the invention. Or, as stated, the entire PCB may comprise circuitized substrates as taught here. Many different combinations are thus possible.

In FIG. 12, there is shown an information handling system 101 in accordance with one embodiment of the invention. System 101 may comprise a personal computer, mainframe computer, computer server, or the like, several types of which are well known in the art. System 101, as taught herein, may include one or more of the electrical assemblies as shown in FIG. 9, including PCB 100, these being represented by numeral 102 in FIG. 12. This completed assembly, shown hidden, may be mounted on a still larger PCB or other substrate 80, one example being a “motherboard” of much larger size, should such a board be required. These components are shown hidden because they are enclosed within and thus behind a suitable housing 105 designed to accommodate the various electrical and other components which form part of system 101. PCB 100 may instead comprise such a motherboard in system 101 and thus include additional electrical assemblies, including additional printed circuit cards mounted thereon, such additional cards in turn also possibly including additional electronic components as part thereof. It is thus seen and understood that the electrical assemblies made in accordance with the unique teachings herein may be utilized in several various structures as part of a much larger system, such as information handling system 101. Further description is not believed necessary.

Since other modifications and changes varied to fit particular operating requirements and environments will be apparent to those skilled in the art, this invention is not considered limited to the example chosen for purposes of this disclosure, and covers all changes and modifications which does not constitute departures from the true spirit and scope of this invention.

Having thus described the invention, what is desired to be protected by Letters Patent is presented in the subsequently appended claims.

What is claimed is:

1. A method of forming a circuitized substrate for use in electronic packages, the steps comprising:
a) providing a joining core layer having an upper surface and a lower surface;
b) disposing a copper layer on said upper surface and said lower surface of said joining core layer;
c) forming a thru-hole in said joining core layer;
d) disposing a conductive adhesive within said thru-hole;
e) removing said copper layers from said joining core layer, creating protrusions of said conductive adhesive above said upper surface and said lower surface of said joining core layer;
f) disposing a first circuitized substrate layer containing conductive features on said upper surface of said joining core layer;
g) disposing a second circuitized substrate layer containing conductive features on said lower surface of said joining core layer; and
h) laminating all of said layers together, forming a subassembly, wherein said conductive adhesive in said thru-hole of said joining core layer electrically connects said first and said second circuitized substrate layers.

2. The method of forming a circuitized substrate as in claim 1, wherein said disposing steps (f) and (g) further comprise adding a metal nub to said conductive features of said circuitized substrate layer thereon.

3. The method of forming a circuitized substrate as in claim 2, the steps further comprising:
i) disposing photoimageable material on said conductive features of said circuitized substrate layer;
j) exposing said photoimageable material;
k) etching said photoimageable material to create openings in said photoimageable material;
l) disposing a layer of copper in said openings of said photoimageable material;
m) disposing a layer of gold plating on said layer of copper in said openings of said photoimageable material; and
n) removing the remainder of said photoimageable material.

4. The method of forming a circuitized substrate utilizing a conductive nub structure as in claim 3, wherein said opening is circular.

5. The method of forming a circuitized substrate as in claim 4, wherein said circular opening is 60 microns in diameter.

6. The method of forming a circuitized substrate as in claim 3, wherein said layer of copper is approximately 0.6 mils thick.

7. The method of forming a circuitized substrate as in claim 3, wherein said layer of gold plating is approximately 4 microns thick.

8. The method of forming a circuitized substrate as in claim 1, wherein said forming a thru-hole hole step (c) is accomplished by using at least one type of laser from the group: UV, IR, and Nd-YAG.

9. The method of forming a circuitized substrate as in claim 3, wherein said disposing a layer of gold plating step (m) creates a surface metallurgy amenable to a joining operation.

10. The method of forming a circuitized substrate as in claim 1, wherein said laminating step (h) is performed at a temperature of approximately 200 degrees C. and a pressure of approximately 1600 psi for a time of approximately 2 hours.

11. A circuitized substrate for use in electronic packages comprising:
a joining core having a first surface and a second surface and a plurality of thru-holes containing a conductive adhesive located therein; and
at least one circuitized substrate including a plurality of electrically conductive features located thereon, said electrically conductive features of said circuitized substrate having a copper nub disposed thereon and metal plating disposed thereon.

12. The circuitized substrate of claim 11, wherein said metal plating comprises gold.

13. The circuitized substrate of claim 11, wherein said conductive adhesive extends above the first and second surface joining core plane.

14. The circuitized substrate of claim 12, wherein said gold plating creates a surface metallurgy amenable to a joining operation.

15. An information handling system (IHS) comprising:
a housing; and
a circuitized substrate positioned substantially within said housing and including a joining core including a first surface and a second surface and a plurality of thru-holes containing a conductive adhesive located therein and at least one circuitized substrate including a plurality of electrically conductive features located thereon, said electrically conductive features of said circuitized substrate having a copper nub disposed thereon and metal plating disposed thereon and at least one electrical component positioned on and electrically coupled to said circuitized substrate.

16. The IHS of claim 15, wherein said information handling system comprises a personal computer.

17. The IHS of claim 15, wherein said information handling system comprises a mainframe computer.

18. The IHS of claim 15, wherein said information handling system comprises a computer server.
